(19) United States
(12) Patent Application Publication
(10) Pub. No.: US 2008/0272489 A1
(43) Pub. Date: Nov. 6, 2008

(54) Package substrate and its solder pad

(75) Inventors: Li-Chih Fang, Hsinchu (TW); Ronald Iwata, Ooita City (JP); Wen-Jeng Fan, Hsinchu (TW)

Correspondence Address: ABELMAN, FRAYNE & SCHWAB, 666 THIRD AVENUE, 10TH FLOOR, NEW YORK, NY, 10017, US

(73) Assignee: Powertech Technology Inc.

(21) Appl. No.: 11/824,448

(22) Filed: Jun. 29, 2007

(30) Foreign Application Priority Data
May 4, 2007 (TW) 96115961

(51) Int. Cl. H01L 23/485

(52) U.S. Cl. 257/738; 257/E23.021

(57) ABSTRACT

A semiconductor chip substrate with solder pad includes: a core layer and at least one conductive structure formed on the surface of the core layer; an insulation layer with at least one patterned opening covering the conductive structure, wherein the patterned opening has a center portion and a plurality of wing portions on the peripheral edge of the center portion to define the exposed area of the conductive structure as the solder pad. The solder pad with wing will improve the adhesion effect between the solder pad and the solder ball.

### BACKGROUND OF THE INVENTION

1. Field of the Invention

The present invention relates to a ball grid array (BGA) substrate, and more especially, to the package substrate with the solder-mask-defined (SMD) solder pad.

2. Background of the Related Art

A substrate is used as a chip carrier in the general BGA package of the semiconductor, wherein the chip is arranged on one surface of the substrate to electrically connect a conductive structure which is formed on the substrate, and a plurality of solder balls are mounted on the opposite surface of the substrate to electrically connect the conductive structure. Furthermore, the solder pads are mounted on a printed circuit board (PCB), so that the chip is electrically connected to the PCB through the conductive structure and the solder balls.

Please refer to FIG. 1a, the substrate 10 includes a core layer 12 and a solder mask layer 14. A conductive structure (not shown) and at least one solder pad 16 which electrically connects the conductive structure are formed on the core layer 12, wherein the solder pad 16 is used to mount the solder ball. The solder pad 16 can be divided in to the SMD solder pad and the non-solder-mask-defined (NSMD) solder pad. The solder pad shown in FIG. 1a is an SMD solder pad 16, wherein the size of the solder pad 16 is bigger than the size of an opening 20 on the solder mask layer 14, so that the exposed area of the solder pad 16 is defined by the opening 20. As shown in FIG. 1b, when the package 2 having SMD solder pads is electrically connected to the PCB 3, the solder balls 18 are used to mount on the pads 16 on PCB 3, wherein because the contacting area between the solder ball 18 and the solder pad 16 is small, the result of the board level temperature cycling test (TCT) is not good, and the crack will easily occur in the mounting face between the solder ball 18 and the solder pad 16 or the stress concentration region where the geometric dimension is not continuous.

The NSMD solder pad is a solder pad 16 whose periphery portion is not covered by the solder mask layer 14, such as shown in FIG. 2a, wherein the top surface of the solder pad 16 and the portion of the core layer 12 around the solder pad 16 are exposed through the opening 20 to mount with the solder ball 18. When the BGA package adopts the NSMD solder pad 16, the TCT result between the solder ball 18 and the solder pad 16 is good. However, as shown in FIG. 2b, because the NSMD solder pad 16 is not covered by the solder mask layer 14, the NSMD solder pad 16 will separate from the core layer 12 easily when the package with NSMD solder pad 16 sustains the external stress, and cause the cracks of the signal lines.

The U.S. Pat. No. 6,201,305 and the TW patent I234838 disclose a kind of NSMD solder pad structure to improve the separation of the solder pad from the core layer. In the U.S. Pat. No. 6,201,305, the solder pad includes a central pad and at least two spokes radiating outward from it, and a solder mask is formed over the conductive structure, wherein an circular opening is formed in the mask such that the central pad and an inner portion of each of the spokes is exposed therethrough, and an outer portion of each of the spokes is covered by the mask. Depending on the foregoing NSMD solder pad structure, the solder ball can be mounted on the exposed central pad and portion of the core layer, simultaneously, so that not only increasing the contacting area between the solder ball and the core layer, but also not easily making the solder pad separate from the core layer. The foregoing idea of NSMD solder pad structure is also applied in the TW patent I234838, in this patent, a plurality of hollow portions are formed in the solder pad, and the outer portion of the solder pad is covered by the solder mask layer. Further, the solder ball is mounted on the inner portion of solder pad and the portion of the core layer which is exposed through the hollow portions, so that the contacting area is increased.

However, the U.S. Pat. No. 6201305 and TW patent I234838 only aim at the improvement in the NSMD pad, wherein the shape of the solder pad is fabricated by complicated and difficult etching processes.

### SUMMARY OF THE INVENTION

In order to solve the foregoing problems, one object of this invention is to provide the package substrate of the semiconductor chip and its solder pad, wherein the contacting areas between the solder pads and the solder balls are increased due to the design of the patterned solder pads, and so as to improve the adhesion effect between the solder pads and the solder balls.

One object of this invention is to provide the package substrate of the semiconductor chip and its solder pad, wherein the patterned solder pads are defined by the patterned openings of the solder mask layer to improve the adhesion condition between the solder pads and the solder balls and to increase the package quality.

One object of this invention is to provide the package substrate of the semiconductor chip and its solder pad to strengthen the adhesion effect between the solder pads and the solder balls, and so as to have the good TCT result.

One object of this invention is to provide the package substrate of the semiconductor chip and its solder pad, wherein the patterned openings of the solder mask layer are fabricated by the general lithography without additional processes, and so as to have the advantage of simple fabrication.

Accordingly, one embodiment of the present invention provides a package substrate of a semiconductor chip, which includes: a core layer; a conductive structure formed on the surface of the core layer; and an insulation layer covering the conductive structure, wherein the insulation layer has at least one patterned opening to expose a portion of the conductive structure as a patterned solder pad, and the patterned opening has a center portion and a plurality of wing portions extending from the peripheral edge of the center portion.

Another embodiment of the present invention provides a solder-mask-defined solder pad, which includes: a central area; and a plurality of wings extending from the peripheral edge of the center area.

### BRIEF DESCRIPTION OF THE DRAWINGS

FIG. 1a and FIG. 1b are respectively a conventional cross-section diagram illustrating the SMD solder pad mounting the solder ball and a diagram illustrating the board-level package;

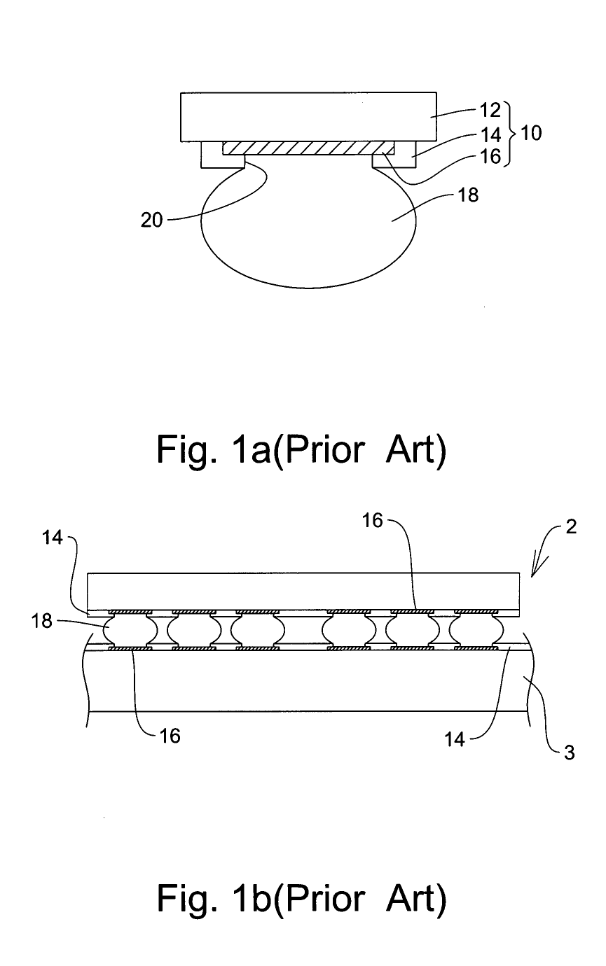

FIG. 2a and FIG. 2b are respectively a conventional cross-section diagram illustrating the NSMD solder pad mounting the solder ball and a diagram illustrating the crack condition between the solder pad and the core layer.

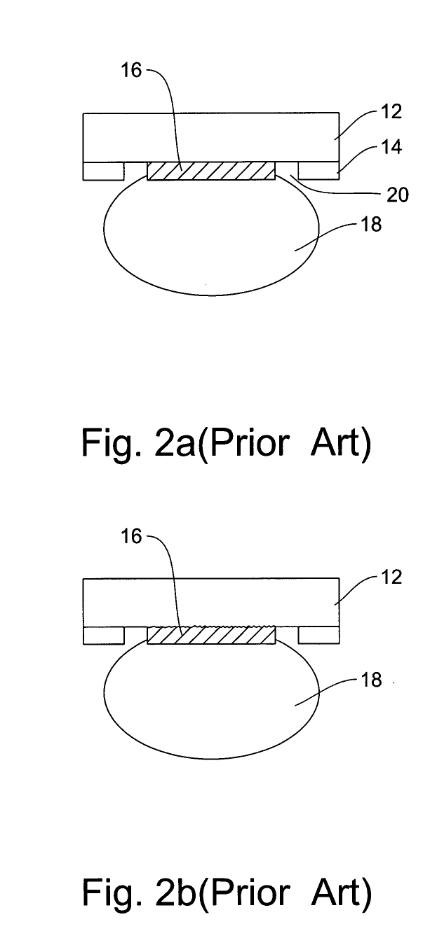

FIG. 3a and FIG. 3b are respectively a vertical view of the package substrate and a cross-section diagram indicated by the section lines of A-A in FIG. 3a in accordance with an embodiment of the present invention; and

FIG. 4 is a diagram illustrating the SMD solder pad in accordance with an embodiment of the present invention.

### DETAILED DESCRIPTION OF THE INVENTION

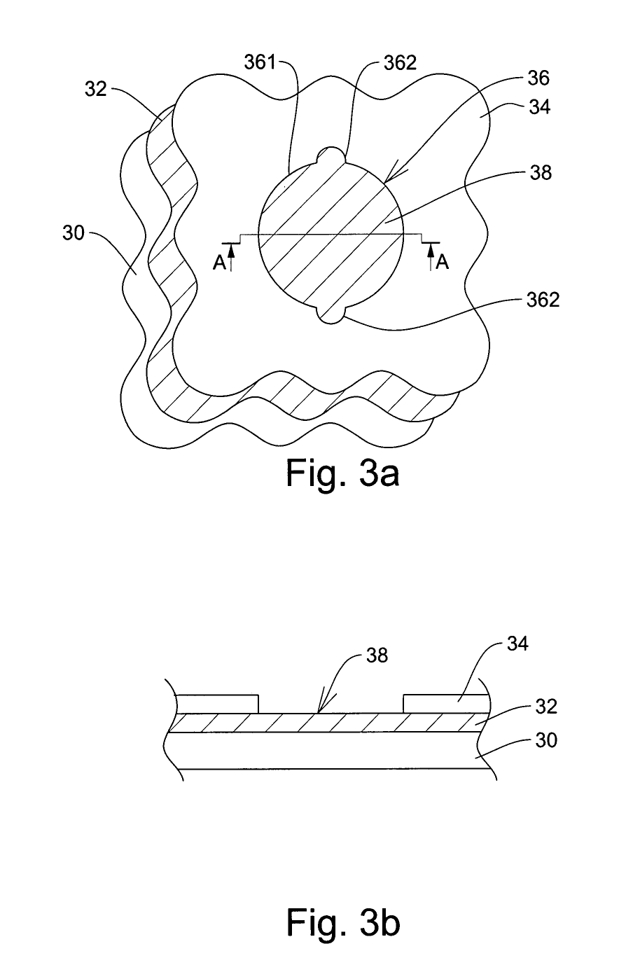

FIG. 3a and FIG. 3b are respectively a vertical view of the package substrate and a cross-section diagram indicated by the section lines of A-A in FIG. 3a in accordance with an embodiment of the present invention. As shown in FIG. 3a and FIG. 3b, the package substrate includes a core layer 30; a conductive structure 32 which predetermines a terminal as the solder pad formed on one surface of the core layer 30; and an insulation layer, such as a solder mask layer 34, formed on the core layer 30 to cover the conductive structure 32. At least one patterned opening 36 is formed on the solder mask layer 34 and the position of the patterned opening 36 corresponds to the position of the terminal, wherein the patterned opening 36 includes a center portion 361 and a plurality of wing portions 362 extending from the peripheral edge of the center portion 361. The center portion 361 and the wing portions 362 are used to define the exposed area of the terminal as the solder pad 38 to mount with the solder ball (not shown).

Continuously, the center portion 361 is circular shape and the wing portions 362 are arched shape. The number of the wing portions 362 may be two or more, and the plurality of wing portions 362 are distributed over the peripheral edge of the center portion 361 with symmetry. In the present invention, the patterned opening 36 with the center portion 361 and the wing portions 362 is fabricated by the lithography, exposure and development, which are the general ways to fabricate the solder mask layer of the package substrate. The material of the core layer 30 is epoxy, polyimide, bismaleimide triazine resin, FR4 resin or FR5 resin. The conductive structure 32 is a patterned metal layer, which is formed by laminating the copper film on the surface of the core layer 30 and then etching and patterning the copper film.

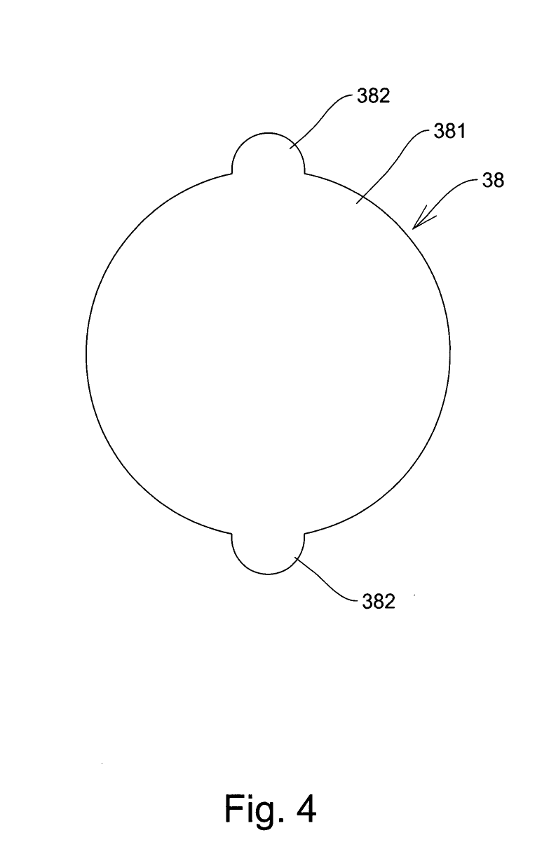

In the present invention, because the opening of the solder mask layer has the circular center portion and the wing portions, as shown in FIG. 4, the solder pad 38 which is defined by the opening will include a center area 381 with circular shape and a plurality of wings 382 with arched shapes extending from the peripheral edge of the center area 381 with symmetry. The solder pad 38 with wings 382 will increase the contacting area between the solder pads and the solder balls to improve the adhesion effect between the solder pads and the solder balls and enhance the package quality. Furthermore, the TCT result will be good depending on the design of the solder pad 38 with the wings 382.

On the other hand, in the present invention, because the shapes of the solder pads are defined by the patterned openings of the solder mask layer, the solder pads will be fabricated by proceeding the lithography to the solder mask layer, and the fabrication of the solder pads are easy. Furthermore, the solder pads on the present invention have the advantages of simple fabrication and good adhesion effect between the solder pads and the solder balls.

Although the present invention has been explained in relation to its preferred embodiment, it is to be understood that other modifications and variation can be made without departing the spirit and scope of the invention as hereafter claimed.

What is claimed is:

1. A package substrate of a semiconductor chip, comprising:
a core layer;
a conductive structure formed on a surface of said core layer; and
an insulation layer over said conductive structure, wherein
said insulation layer has at least a patterned opening to expose a portion of said conductive structure as a patterned solder pad, and said patterned opening has a center portion and a plurality of wing portions extending from a peripheral edge of said center portion.

2. The package substrate of the semiconductor chip according to claim 1, wherein, said conductive structure is a patterned metal layer.

3. The package substrate of the semiconductor chip according to claim 1, wherein said insulation layer is a solder mask layer.

4. The package substrate of the semiconductor chip according to claim 1, wherein said plurality of wing portions are distributed over said peripheral edge of said center portion with symmetry.

5. The package substrate of the semiconductor chip according to claim 1, wherein said center portion is circular shape.

6. The package substrate of the semiconductor chip according to claim 1, wherein said wing portions are arched shape.

7. A solder-mask-defined solder pad, comprising:
a central area; and
a plurality of wings extending from a peripheral edge of said center area.

8. The solder-mask-defined solder pad according to claim 7, wherein said plurality of wings are distributed over said peripheral edge of said center area with symmetry.

9. The solder-mask-defined solder pad according to claim 7, wherein said center area is circular shape.

10. The solder-mask-defined solder pad according to claim 7, wherein said wings are arched shape.
